(19) United States
(12) Patent Application Publication
(10) Pub. No.: US 2026/0173982 A1
(43) Pub. Date: Jun. 18, 2026

(54) SEMICONDUCTOR MODULE

(71) Applicant: Mitsubishi Electric Corporation, Tokyo (JP)

(72) Inventors: Shohei SHIMADA, Tokyo (JP); Naoki IKEDA, Tokyo (JP); Shimpei KASAHARA, Tokyo (JP)

(73) Assignee: Mitsubishi Electric Corporation, Tokyo (JP)

(21) Appl. No.: 19/406,866

(22) Filed: Dec. 2, 2025

(30) Foreign Application Priority Data
Dec. 13, 2024 (JP) 2024-218639

(51) Int. Cl. H10W 90/00

(52) U.S. Cl. CPC H10W 90/751; H10W 72/527; H10W 74/111; H10W 90/753; H10W 90/756; H10W 90/811

(57) ABSTRACT

A semiconductor module includes: a lead frame; a semiconductor element mounted to the lead frame; a first wire connected to the semiconductor element or the lead frame and contributing to an operation of the semiconductor element; a second wire connected the lead frame and not contributing to an operation of the semiconductor element; and sealing resin sealing a part of the lead frame, the semiconductor element, the first wire, and the second wire. The second wire has a smaller diameter or elastic coefficient than the first wire.

### BACKGROUND

### Technical Field

The present disclosure relates to a semiconductor module.

### Description of the Background Art

A semiconductor module having a structure sealed with resin is widely known. Sealing resin of the semiconductor module is generally formed by locating a lead frame wired by a wire and a semiconductor element in a mold and injecting and molding resin in the mold. At this time, when the wire is pressed by the resin flowing in the mold and deformation (also referred to as “sweep”) or disconnection of the wire occurs, a conduction failure (open) or an insulation failure (short) of a circuit occurs in the semiconductor module.

The insulation failure and the conduction failure of the semiconductor module can be detected by a conduction test. However, a latent failure (an excess sweep and a partial disconnection) of the wire which does not lead to the insulation failure and the conduction failure cannot be detected by the conduction test, and may cause the insulation failure and the conduction failure after the semiconductor module comes on the market. Thus, techniques of detecting the latent failure of the wire are variously proposed.

For example, Japanese Patent Application Laid-Open No. 11-126861 described hereinafter discloses a technique of providing a mark to a lead frame as a basis of presence or absence of a sweep of a wire and confirming a positional relationship between the wire and the mark by an X-ray inspection apparatus, thereby determining non-defective and defective of the wire. Japanese Patent Application Laid-Open No. 2005-286009 described hereinafter discloses a technique of providing a dummy wire having small connection strength near a wire constituting a circuit and detecting detachment of the dummy wire using a detection circuit, thereby predicting detachment of the wire constituting the circuit.

### SUMMARY

A visual examination using the X-ray detection apparatus is necessary for the technique according to Japanese Patent Application Laid-Open No. 11-126861, and it takes a lot of trouble in determining non-defective and defective of the wire. In the technique according to Japanese Patent Application Laid-Open No. 2005-286009, the detachment of the wire can be predicted. However, it is difficult to predict the sweep and the disconnection of the wire. Instead, in the technique according to Japanese Patent Application Laid-Open No. 2005-286009, a diameter of the dummy wire is thicker than a normal wire to set the connection strength of the dummy wire to be weak. Thus, the sweep and disconnection occur more hardly in the dummy wire than in the wire constituting the circuit.

An object of the present disclosure is to prevent outflow of a semiconductor module including a latent failure in a wire.

A semiconductor module according to the present disclosure includes: at least one lead frame; a semiconductor element mounted to the lead frame; a first wire connected to the semiconductor element or the lead frame and contributing to an operation of the semiconductor element; a second wire connected the lead frame and not contributing to an operation of the semiconductor element; and sealing resin sealing a part of the lead frame, the semiconductor element, the first wire, and the second wire. The second wire has a smaller diameter or elastic coefficient than the first wire.

According to the technique of the present disclosure, outflow of a semiconductor module including a latent failure in a wire can be prevented.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view illustrating an inner structure of a semiconductor module according to an embodiment 1.

FIG. 2 is an appearance diagram of the semiconductor module according to the embodiment 1.

FIG. 3 is a plan view illustrating an inner structure of a semiconductor module according to an embodiment 2.

FIG. 4 is an appearance diagram of the semiconductor module according to the embodiment 2.

FIG. 5 is a cross-sectional view of the semiconductor module according to the embodiment 2.

FIG. 6 is a cross-sectional view illustrating occurrence of a sweep in a dummy wire in the semiconductor module according to the embodiment 2.

FIG. 7 is an explanation diagram of an insulation withstand voltage test of the semiconductor module according to the embodiment 2.

FIG. 8 is a plan view illustrating an inner structure of a semiconductor module according to an embodiment 3.

FIG. 9 is an appearance diagram of the semiconductor module according to the embodiment 3.

FIG. 10 is a cross-sectional view of the semiconductor module according to the embodiment 3.

FIG. 11 is a diagram for explaining an insulation withstand voltage test of the semiconductor module according to the embodiment 3.

### DESCRIPTION OF THE PREFERRED EMBODIMENTS

### Embodiment 1

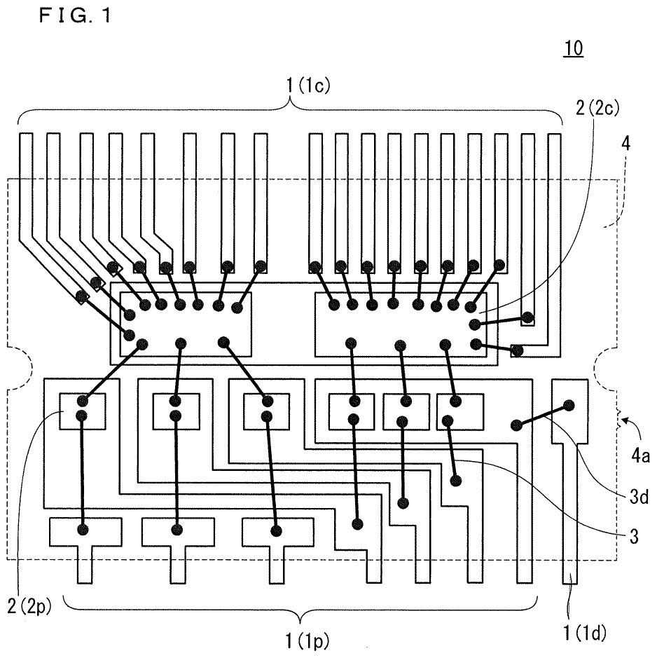

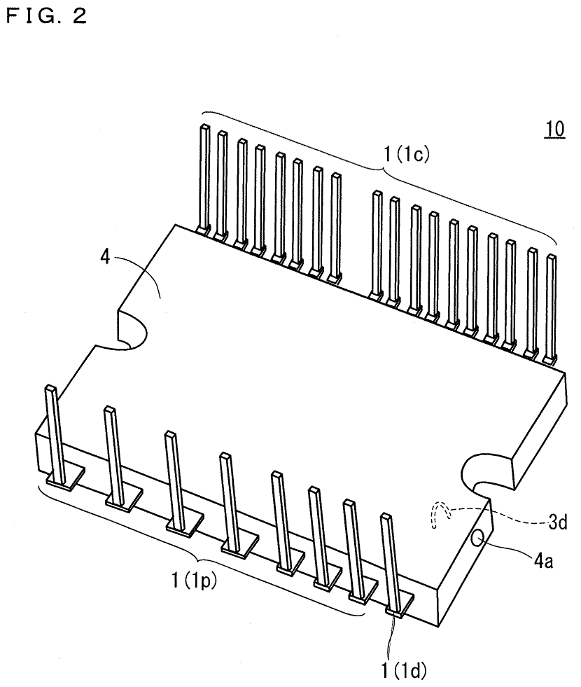

FIG. 1 is a plan view illustrating an inner structure of a semiconductor module 10 according to an embodiment 1. FIG. 2 is an appearance diagram of the semiconductor module 10.

As illustrated in FIG. 1, the semiconductor module 10 includes a plurality of lead frames 1, a semiconductor element 2 mounted to the lead frame 1, a wire 3 connected to the semiconductor element 2 or the lead frame 1, and a dummy wire 3d connected to the lead frame 1 separately from the wire 3. The lead frame 1, the semiconductor element 2, the wire 3, and the dummy wire 3d are sealed by sealing resin 4. A part of the lead frame 1 protrudes from the sealing resin 4 to function as an external connection terminal. FIG. 1 illustrates only an outline of the sealing resin 4 by a dotted line. The configuration of the semiconductor module 10 illustrated in FIG. 1 and FIG. 2 are merely an example, thus is not limited thereto.

The semiconductor element 2 includes a power element 2p for controlling electrical power and a control integrated circuit (IC) 2c controlling an operation of the power element 2p, for example. There is no limitation on a type of the power element 2p. Assumed is, for example, a metal oxide semiconductor field effect transistor (MOSFET), an insulated gate bipolar transistor (IGBT), a Schottky barrier diode, and a PN junction diode. The lead frame 1 includes a power-side lead frame 1p connected to a main electrode of the power element 2p, a control-side lead frame 1c connected to the control IC 2c, and a dummy frame 1d which does not contribute to an operation of the power element 2p and the control IC 2c.

The wire 3 is a first wire contributing to an operation of the semiconductor element 2. The dummy wire 3d is a second wire which does not contribute to an operation of the semiconductor element 2. The dummy wire 3d has a smaller diameter or elastic coefficient than the wire 3. In the present embodiment, the dummy wire 3d is connected between the power-side lead frame 1p and the dummy frame 1d.

The dummy wire 3d has a smaller diameter or elastic coefficient than the wire 3, thus is disconnected in a process of molding the sealing resin 4 more easily than the wire 3. Thus, presence or absence of disconnection of the dummy wire 3d is confirmed after forming the sealing resin 4, and when the dummy wire 3d is not disconnected, it can be determined that the wire 3 is in a favorable state and there is a low possibility of a latent failure in the wire 3. In contrast, when the dummy wire 3d is disconnected, it can be determined that there is a high possibility of a latent failure in the wire 3.

The presence or absence of the disconnection of the dummy wire 3d can be confirmed by a conduction test between the power-side lead frame 1p and the dummy frame 1d to which the dummy wire 3d is connected. That is to say, when there is a conduction between the power-side lead frame 1p and the dummy frame 1d to which the dummy wire 3d is connected, it can be determined that the dummy wire 3d is not disconnected, and when there is no conduction therebetween, it can be determined that the dummy wire 3d is disconnected.

In this manner, when screening is performed on the semiconductor module 10 by determining a possibility of a latent failure of the wire 3 based on the presence or absence of the disconnection of the dummy wire 3d, outflow of the semiconductor module 10 in which the wire 3 has a latent failure to the market can be prevented.

A resin injection mark 4a as a mark of a resin injection inlet of a mold used for molding the sealing resin 4 remains in a surface of the sealing resin 4 (generally a side surface). The dummy wire 3d is preferably disposed closer to the resin injection mark 4a than the wire 3 is. That is to say, the dummy wire 3d is preferably located near the resin injection inlet of the mold in the process of molding the sealing resin 4. Since a flow of the resin has large influence and the dummy wire 3d is easily disconnected near the resin injection inlet, a possibility of outflow of the semiconductor module 10 in which the wire 3 has a latent failure can be further reduced.

The wire 3 connected to the power-side lead frame 1p generally has a larger line shape than the wire 3 connected to the control-side lead frame 1c, and a sweep or a disconnection hardly occurs. Thus, from a viewpoint of preventing the sweep or the disconnection of the wire 3, the resin injection inlet of the mold is provided near the power-side lead frame 1p (as a result, the resin injection mark 4a is located near the power-side lead frame 1p). Thus, in the present embodiment, the dummy wire 3d is connected to the power-side lead frame 1p.

In the process of molding the sealing resin 4, there may be a case where molds of the plural pieces of the sealing resin 4 are provided to one mold, and the plurality of semiconductor modules 10 are sealed at the same time. In this case, since one piece of sealing resin 4 includes a resin injection inlet and a resin flow outlet, a mark of the resin injection inlet (the resin injection mark 4a) and a mark of the resin flow outlet are left in the sealing resin 4. Although it is difficult to distinguish which mark is the resin injection mark 4a from an appearance of the semiconductor module 10, it can be estimated that the mark located closer to the power-side lead frame 1p is the resin injection mark 4a from a viewpoint of preventing the sweep and the disconnection of the wire 3. It can be determined which mark is the resin injection mark 4a by observing a direction of a sweep occurring in the wire 3 and the dummy wire 3d by a method such as an analysis using X-ray or opening of the sealing resin 4 and determining a direction in which the resin flows.

Although FIG. 1 and FIG. 2 illustrate an example that the side surface of the sealing resin 4 with no external connection terminal includes the resin injection mark 4a, there is no limitation on a position of the resin injection mark 4a. For example, the resin injection mark 4 may be located between external connection terminals in the side surface of the sealing resin 4 including an external connection terminal.

Described in the present embodiment is the example that the dummy wire 3d is connected between the power-side lead frame 1p and the dummy frame 1d. However, it is also applicable that two dummy frames 1d are provided to the semiconductor module 10 and connected between two dummy frames 1d. In such a case, the presence or absence of the disconnection of the dummy wire 3d can be confirmed by a conduction test between two dummy frames 1d to which the dummy wire 3d is connected.

### Embodiment 2

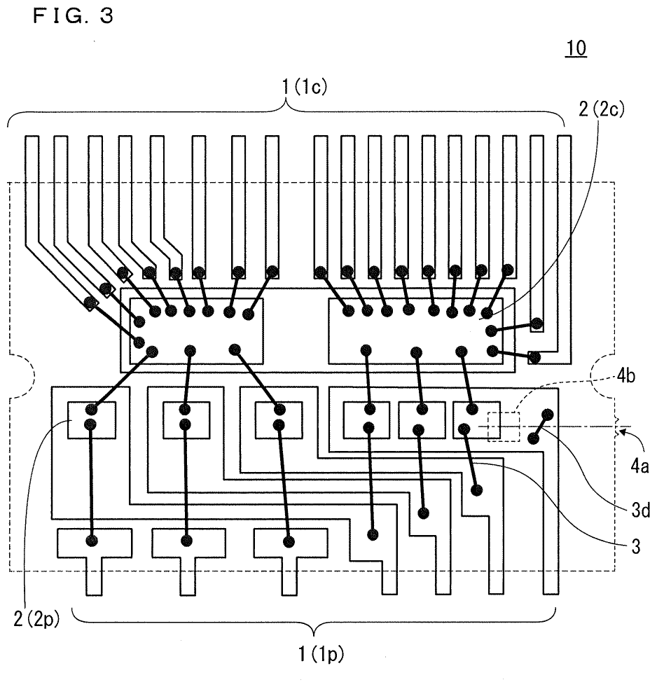

FIG. 3 is a plan view illustrating an inner structure of the semiconductor module 10 according to an embodiment 2. FIG. 4 is an appearance diagram of the semiconductor module 10.

The semiconductor module 10 according to the embodiment 2 does not include the dummy frame 1d, and both ends of the dummy wire 3d are connected to one lead frame 1 (the power-side lead frame 1p). As illustrated in FIG. 4, the sealing resin 4 includes a depression 4b formed in a surface thereof. The depression 4b is disposed near the dummy wire 3d, and the wire 3 is not located between the depression 4b and the dummy wire 3d. FIG. 3 illustrates the depression 4b by a dotted line. The depression 4b is disposed closer to a downstream side than the dummy wire 3d is in a flow direction of the resin injected from the resin injection inlet of the mold in the process of molding the sealing resin 4. Thus, the dummy wire 3d is disposed between the resin injection mark 4a and the depression 4b in a plan view. At this time, a top (a highest part) of the dummy wire 3d is preferably located in a straight line connecting the resin injection mark 4a and the depression 4b in a plan view.

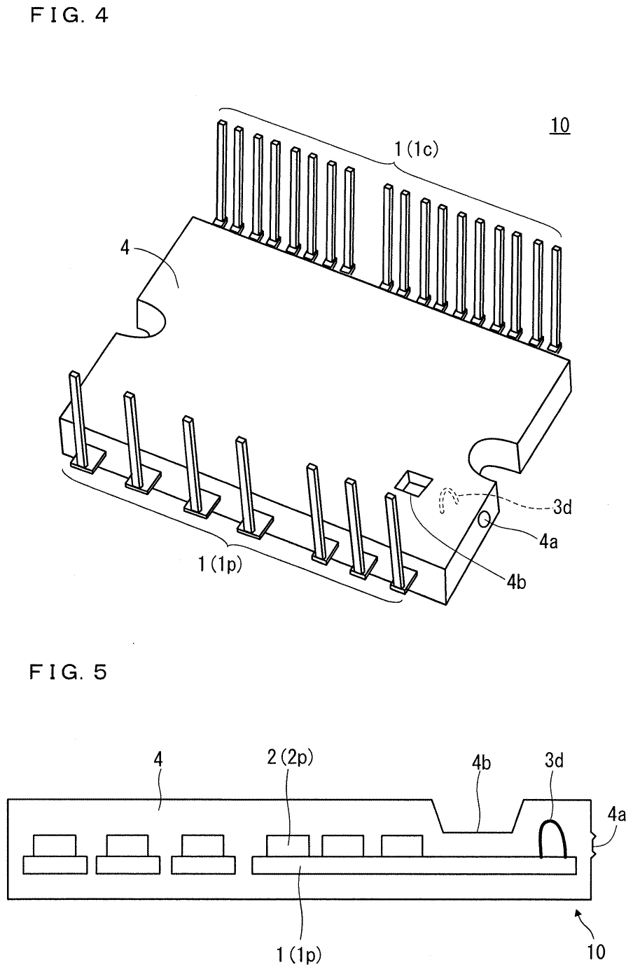

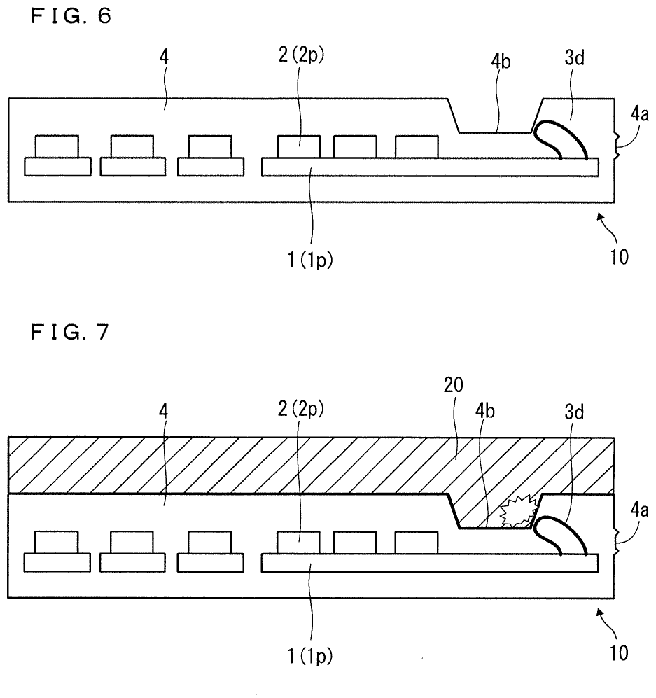

FIG. 5 and FIG. 6 schematically illustrate a cross section passing the dummy wire 3d, the resin injection mark 4a, and the depression 4b in the semiconductor module 10. Since the dummy wire 3d has the smaller diameter or elastic coefficient than the wire 3, a sweep occurs in the dummy wire 3d in the process of molding the sealing resin 4 more easily than the wire 3. Thus, the presence or absence of sweep of the dummy wire 3d is confirmed after forming the sealing resin 4, and when the sweep does not occur in the dummy wire 3d as illustrated in FIG. 5, it can be determined that the wire 3 is in a favorable state and there is a low possibility of a latent failure in the wire 3. In contrast, when the sweep occurs in the dummy wire 3d, it can be determined that there is a high possibility of a latent failure in the wire 3.

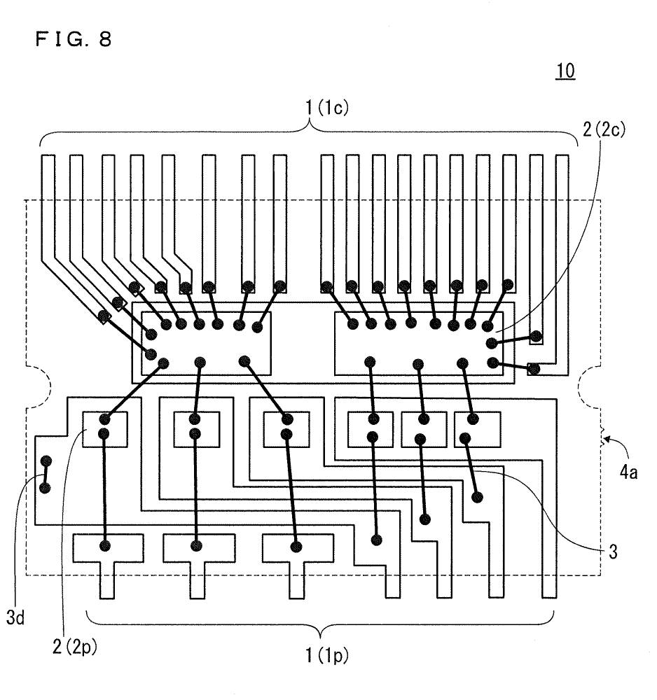

The presence or absence of the sweep of the dummy wire 3d can be confirmed by performing an insulation withstand voltage test on the sealing resin 4 between the lead frame 1 (the power-side lead frame 1p) to which the dummy wire 3d is connected and an insulation withstand voltage test jig 20 illustrated in FIG. 7 using the insulation withstand voltage test jig 20. A convex part fitted into the depression 4b of the sealing resin 4 is provided to the insulation withstand voltage test jig 20. Since the depression 4b is disposed closer to a downstream side of the flow direction of the resin than the dummy wire 3d is, the top of the dummy wire 3d in which the sweep occurs gets close to the depression 4b, and causes a withstand voltage failure of the sealing resin 4. When the presence or absence of the withstand voltage failure is confirmed by the insulation withstand voltage test, the presence or absence of the sweep of the dummy wire 3d can be confirmed. That is to say, when the withstand voltage failure does not occur, it can be determined that the sweep does not occur in the dummy wire 3d, and when the withstand voltage failure occurs, it can be determined that the sweep occurs in the dummy wire 3d.

In this manner, when screening is performed on the semiconductor module 10 by determining the presence or absence of the latent failure of the wire 3 based on the presence or absence of the sweep of the dummy wire 3d, outflow of the semiconductor module 10 in which the wire 3 has a latent failure to the market can be prevented.

Also in the present embodiment, the dummy wire 3d is preferably disposed closer to the resin injection mark 4a than the wire 3 is. Although the present embodiment describes the example of connecting the dummy wire 3d to one power-side lead frame 1p, it is also applicable that the dummy frame 1d is provided to the semiconductor module 10 and the dummy wire 3d is connected to the dummy frame 1d. In such a case, the presence or absence of the sweep of the dummy wire 3d can be confirmed by performing the insulation withstand voltage test on the sealing resin 4 between the dummy frame 1d to which the dummy wire 3d is connected and the insulation withstand voltage test jig 20.

### Embodiment 3

FIG. 8 is a plan view illustrating an inner structure of the semiconductor module 10 according to an embodiment 3. FIG. 9 is an appearance diagram of the semiconductor module 10.

In the manner similar to the embodiment 2, the semiconductor module 10 according to the embodiment 3 does not include the dummy frame 1d, and both ends of the dummy wire 3d are connected to one lead frame 1 (the power-side lead frame 1p). However, the dummy wire 3d is disposed near the side surface of the sealing resin 4 as a most downstream part in the flow direction of the resin injected from the resin injection inlet of the mold in the process of molding the sealing resin 4. The wire 3 is not located between the side surface of the sealing resin 4 and the dummy wire 3d. Thus, the dummy wire 3d is disposed near the surface of the sealing resin 4 on a side opposite to the surface thereof including the resin injection mark 4a. The depression 4b described in the embodiment 2 needs not be provided to the semiconductor module 10 according to the embodiment 3.

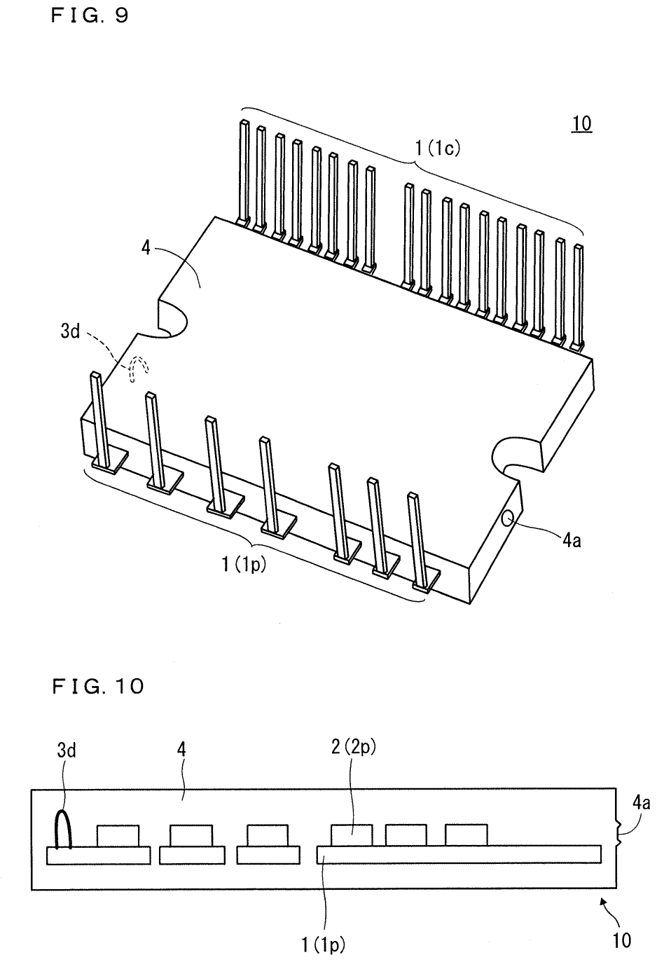

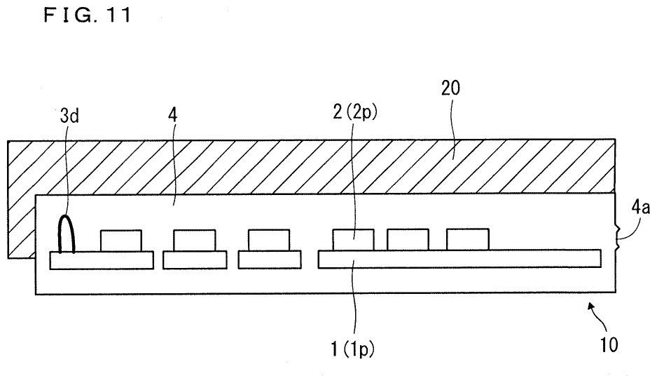

FIG. 10 schematically illustrates a cross section passing the dummy wire 3d, the resin injection mark 4a, and the depression 4b in the semiconductor module 10. Since the dummy wire 3d has the smaller diameter or elastic coefficient than the wire 3, a sweep occurs in the dummy wire 3d in the process of molding the sealing resin 4 more easily than the wire 3. Thus, the presence or absence of sweep of the dummy wire 3d is confirmed after forming the sealing resin 4, and when the sweep does not occur in the dummy wire 3d, it can be determined that the wire 3 is in a favorable state and there is a low possibility of a latent failure in the wire 3. In contrast, when the sweep occurs in the dummy wire 3d, it can be determined that there is a high possibility of a latent failure in the wire 3.

The presence or absence of the sweep of the dummy wire 3d can be confirmed by performing the insulation withstand voltage test on the sealing resin 4 between the lead frame 1 (the power-side lead frame 1p) to which the dummy wire 3d is connected and the insulation withstand voltage test jig 20 illustrated in FIG. 7 using the insulation withstand voltage test jig 20. The convex part covering the side surface of the sealing resin 4 near the dummy wire 3d is provided to the insulation withstand voltage test jig 20. Since the dummy wire 3d is disposed in the most downstream part in the flow direction of the resin, the top of the dummy wire 3d in which the sweep occurs gets close to the side surface of the sealing resin 4, and causes a withstand voltage failure of the sealing resin 4. When the presence or absence of the withstand voltage failure is confirmed by the insulation withstand voltage test, the presence or absence of the sweep of the dummy wire 3d can be confirmed. That is to say, when the withstand voltage failure does not occur, it can be determined that the sweep does not occur in the dummy wire 3d, and when the withstand voltage failure occurs, it can be determined that the sweep occurs in the dummy wire 3d.

In this manner, when screening is performed on the semiconductor module 10 by determining the presence or absence of the latent failure of the wire 3 based on the presence or absence of the sweep of the dummy wire 3d, outflow of the semiconductor module 10 in which the wire 3 has a latent failure to the market can be prevented.

Although the present embodiment describes the example of connecting the dummy wire 3d to one power-side lead frame 1p, it is also applicable that the dummy frame 1d is provided to the semiconductor module 10 and the dummy wire 3d is connected to the dummy frame 1d. In such a case, the presence or absence of the sweep of the dummy wire 3d can be confirmed by performing the insulation withstand voltage test on the sealing resin 4 between the dummy frame 1d to which the dummy wire 3d is connected and the insulation withstand voltage test jig 20.

Each embodiment can be arbitrarily combined, or each embodiment can be appropriately varied or omitted.

### Appendix

The aspects of the present disclosure are collectively described hereinafter as appendixes.

### (Appendix 1)

A semiconductor module, comprising:
at least one lead frame;
a semiconductor element mounted to the lead frame;
a first wire connected to the semiconductor element or the lead frame and contributing to an operation of the semiconductor element;
a second wire connected the lead frame and not contributing to an operation of the semiconductor element; and
sealing resin sealing a part of the lead frame, the semiconductor element, the first wire, and the second wire, wherein
the second wire has a smaller diameter or elastic coefficient than the first wire.

### (Appendix 2)

The semiconductor module according to Appendix 1, comprising
the plurality of lead frames,
the plurality of lead frames include at least one dummy frame which does not contribute to an operation of the semiconductor element, and
the second wire is connected between the dummy frame and the lead frame or between the two dummy frames.

### (Appendix 3)

The semiconductor module according to Appendix 1, wherein
the sealing resin includes a depression disposed near the second wire, and
the second wire is disposed between a resin injection mark of the sealing resin and the depression.

### (Appendix 4)

The semiconductor module according to Appendix 3, wherein
a top of the second wire is located in a straight line connecting the resin injection mark and the depression in a plan view.

### (Appendix 5)

The semiconductor module according to any one of Appendixes 2 to 4, wherein
the second wire is disposed near the resin injection mark of the sealing resin.

### (Appendix 6)

The semiconductor module according to Appendix 1, wherein
the second wire is disposed near a surface of the sealing resin on a side opposite to a surface of the sealing resin including the resin injection mark.

While the disclosure has been shown and described in detail, the foregoing description is in all aspects illustrative and not restrictive. It is therefore understood that numerous modifications and variations can be devised.

What is claimed is:

1. A semiconductor module, comprising:
at least one lead frame;
a semiconductor element mounted to the lead frame;
a first wire connected to the semiconductor element or the lead frame and contributing to an operation of the semiconductor element;
a second wire connected the lead frame and not contributing to an operation of the semiconductor element; and
sealing resin sealing a part of the lead frame, the semiconductor element, the first wire, and the second wire, wherein
the second wire has a smaller diameter or elastic coefficient than the first wire.

2. The semiconductor module according to claim 1, comprising
the plurality of lead frames,
the plurality of lead frames include at least one dummy frame which does not contribute to an operation of the semiconductor element, and
the second wire is connected between the dummy frame and the lead frame or between the two dummy frames.

3. The semiconductor module according to claim 1, wherein
the sealing resin includes a depression disposed near the second wire, and
the second wire is disposed between a resin injection mark of the sealing resin and the depression.

4. The semiconductor module according to claim 3, wherein
a top of the second wire is located in a straight line connecting the resin injection mark and the depression in a plan view.

5. The semiconductor module according to claim 2, wherein
the second wire is disposed near the resin injection mark of the sealing resin.

6. The semiconductor module according to claim 3, wherein
the second wire is disposed near the resin injection mark of the sealing resin.

7. The semiconductor module according to claim 4, wherein
the second wire is disposed near the resin injection mark of the sealing resin.

8. The semiconductor module according to claim 1, wherein
the second wire is disposed near a surface of the sealing resin on a side opposite to a surface of the sealing resin including the resin injection mark.
